(19) United States
(12) Patent Application Publication
(10) Pub. No.: US 2009/0147807 A1
(43) Pub. Date: Jun. 11, 2009

(54) Fiber grating laser

(76) Inventors: Yicheng Lai, Singapore (SG); Amos Martinez, Tokyo (JP); Ian Bennion, Northants (GB)

Correspondence Address: Buchanan Intellectual Property Office LLC, P.O. Box 700, Perrysburg, OH, 43552-0700, US

(21) Appl. No.: 11/920,366

(22) PCT Filed: May 12, 2006
(86) PCT No.: PCT/GB2006/001772

§ 371 Date: Dec. 18, 2008

(30) Foreign Application Priority Data
May 14, 2005 (GB) 0509920.5

(51) Int. Cl. H01S 3/30; H01L 21/02

(52) U.S. Cl. 372/6; 438/32; 257/E21.002

(57) ABSTRACT

A fiber (Bragg) laser comprising a fiber with a cladding and a core having a (Bragg) grating inscribed in the core forming a laser cavity.

This invention relates to a fiber laser and method of producing the same.

Is known to provide rare earth doped fiber Bragg grating (FBG) lasers as an alternative to the standard semiconductor lasers in a wide range of communication, sensor and spectroscopic applications.

It is known to produce fiber laser with such doped fibers by splicing a length of fiber to fiber Bragg gratings However, this does not allow precise control of the resonator characteristics e.g. the cavity length, and suffers from inter-cavity losses associated with splicing of gratings to the gain fiber.

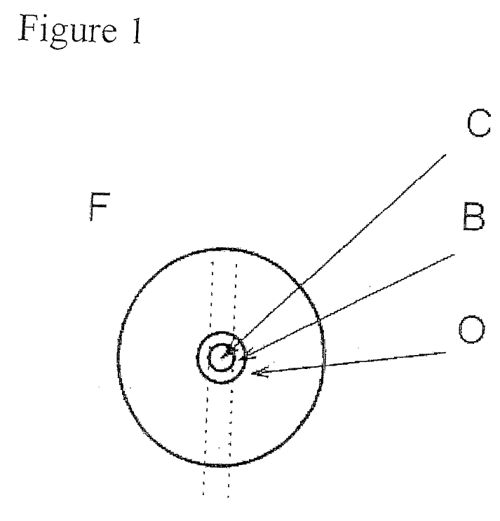

It is known to provide a fiber laser written with UV light, as a short length liner cavity in a special double cladded Er:Yb co-doped phosphosilicate lasers fiber. The cross section of such as fiber laser is depicted in FIG. 1. Such double cladded fiber is difficult and expensive to produce. Additionally UV writing can produce fiber laser in less desirable fiber material such as Er doped germanosilicate fiber.

However, UV writing in such doubled cladded fiber lasers does not produce significant polarization dependent characteristics in the inscribed grating laser structure. Consequently it is not possible to easily tailor the polarization characteristics of such fiber grating lasers nor to produce a fiber laser that can maintain a single polarization mode operation over a temperature range and in particular at high temperatures. Known fiber Bragg lasers with gratings in the core have dual-polarization mode operation but it is not easy to control the mode separation.

It is an object of the present invention to mitigate some or all of the above problems.

According to a first aspect of the invention there is provided a fiber laser comprising a gain fiber which is doped with at least one gain inducing material and has one or more gratings inscribed in the gain fiber forming a laser cavity

According to a second aspect of the invention there is provided a fiber Bragg laser comprising a fiber with a cladding and a core, preferably doped with at least one gain inducing material, having one or more Bragg gratings inscribed in the core forming a laser cavity.

According to a third aspect of the invention there is provided a method of fabricating a fiber Bragg laser comprising the steps of: focussing a laser, preferably with a wavelength between about 450 to 1000 and more preferably around 800 nm, into the core of an optical fiber at a power sufficient to alter the refractive index at the point of focus and repeating the focussing step at multiple points along the core to produce one or more plurality of fiber Bragg gratings to create a laser cavity.

Preferably the gain inducing material is a rare earth such as Ytterbium or Erbium or the core/gain fiber is Er:Yb co-doped gain fiber and preferably untreated Er:Yb co-doped gain fiber.

Preferably the fiber/cladding/core comprises a non-photosensitive material such as phosphosilicate glass.

The laser may have a Distributed Bragg Reflector (DBR) configuration or distributed feedback (DFB) configuration

Preferably a diode laser is the pump source.

Preferably the diode laser is able to run in continuous operation at high temperatures such as 500 or 1000 degrees Celsius and/or at room temperature.

Preferably the inscribed grating cavity has polarization dependent characteristics and/or has a single or dual polarization mode which is more preferably maintained over a temperature range such as 0 to 300 degrees and preferably 0 to 1000 degrees Celsius.

Preferably there is birefringence in the grating(s). Preferably the grating has a refractive index profile comprising regions of higher refractive index separated by regions of substantially constant refractive index. Inscribed gratings may have different Bragg wavelengths and the fiber laser may have tailored polarization characteristics so that it operably has varying output polarization states at different wavelengths.

Preferably the grating is located in an off centre segment of the fiber so that the profile of the refractive index of the core/gain fiber is asymmetrical and different in different planes of the fiber cross section.

The invention may be incorporated within a single polarisation device, a microwave signal generator or a sensing device.

Preferably the polarization characteristics of the fabricated laser are tailored to produce a fiber laser with single polarization mode operation preferably with polarization purity in excess of 40 dB or with dual polarization mode and the mode separation can be increased or decreased.

Preferably the focussed laser used in the method is a pulsed laser preferably pulsed at a rate around 1 kHz and/or is a femtosecond laser and the pulses preferably have a duration of around 150 fs. Preferably the fiber is moved relative to the laser at a substantially constant speed and/or wherein the speed is selected relative to the laser pulse rate so that the distanced travelled between pulses corresponds to the pitch of gratings inscribed. Preferably still the focussed laser is synchronised with a shutter to generate the desired gap between gratings for the desired cavity length.

Embodiments of the invention will now be described, by way of example only, with reference to the company drawings in which:

FIG. 1 is a cross sectional view of a prior art FBG laser;

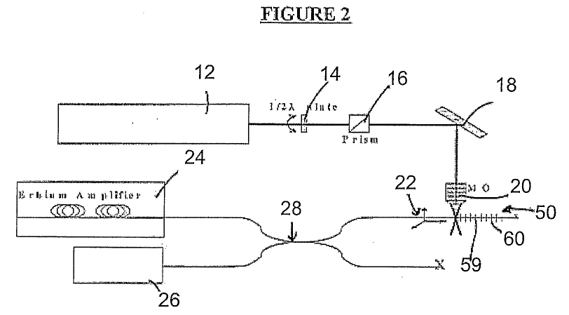

FIG. 2 is a system for inscribing a grating structure in accordance with the invention;

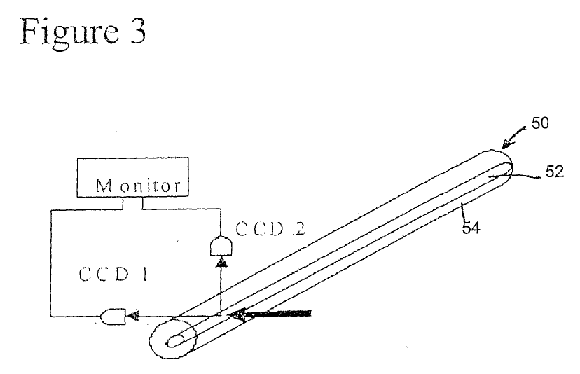

FIG. 3 is a schematic drawing of monitoring the refractive index in an inscribed grating according to the invention;

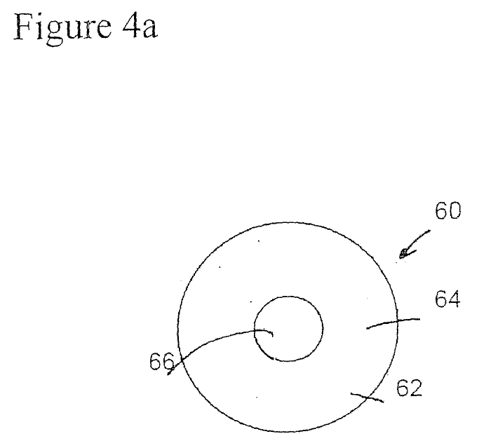

FIG. 4a is a schematic cross sectional view of the inscribed optical fiber according to the invention;

FIG. 4b is a schematic longitudinal section view of the inscribed optical fiber according to the invention;

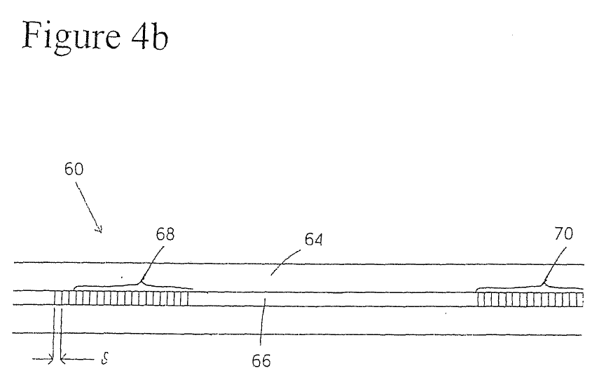

FIG. 5 is a transmission profile of the fiber laser cavity created in FIG. 3 that shows distinct resonance peaks;

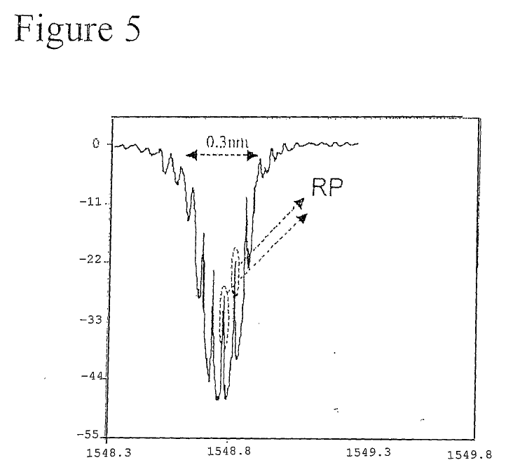

FIG. 6 is a view of the fiber laser output optical spectrum during operation of the cavity of FIG. 5;

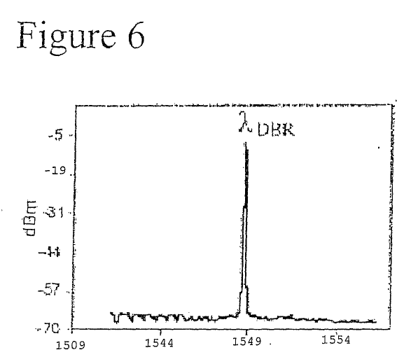

FIG. 7 is the measured output intensity noise of the laser from the FBG of FIGS. 5 and 6;

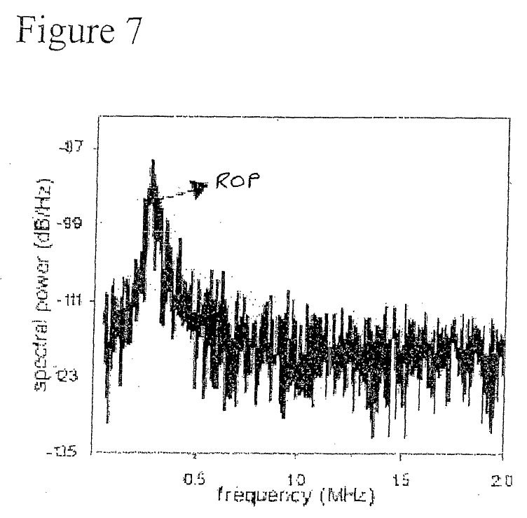

FIG. 8 illustrates the output power of the laser output of FIG. 7 over a period of time;

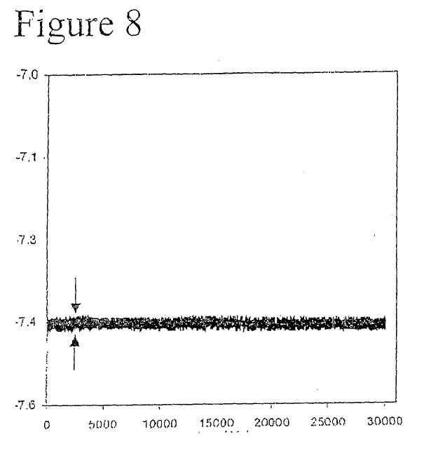

FIG. 9 shows the wavelength shifts of fiber laser output and their uniform FBG in Er:Yb co-doped fiber against temperature;

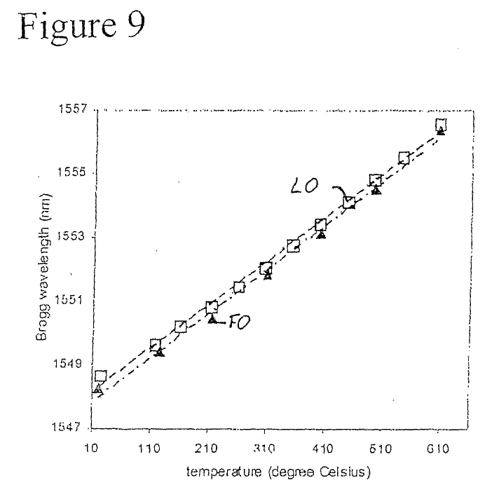

FIG. 10 illustrates the fiber laser output at a particular temperature;

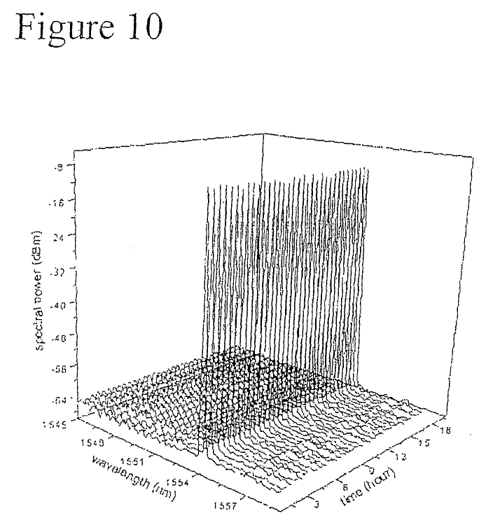

FIG. 11 is a schematic cross sectional view of a second embodiment of inscribed optical fiber according to the invention; and

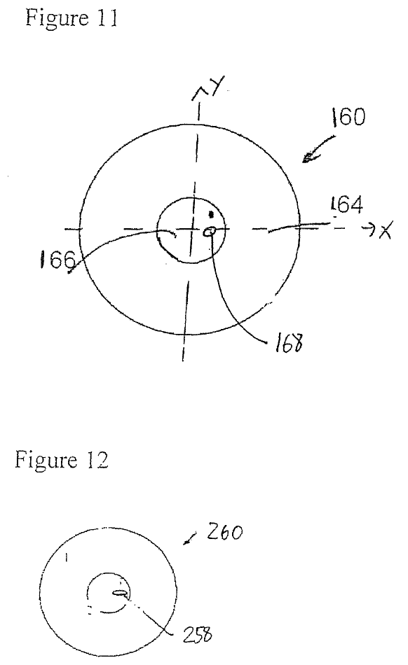

FIG. 12 is a schematic cross sectional view of a third embodiment of inscribed optical fiber according to the invention;

Referring to FIG. 1, there is shown a cross section of double clammed Er:Yb Fiber with a UV inscribed grating cavity known in the prior art. The fiber F comprises a Er:Yb doped phosphosilicate core C, a highly photosensitive B/Ge doped silica inner cladding B and standard outer cladding O. The germanium doping and boron doping are at the correct levels so that the same refractive index occurs through the inner cladding being B as in the undoped outer silica cladding O. This can be achieved since the germanium doping increases the refractive index and boron doping lowers it. The inner cladding B is highly photosensitive allowing gratings to be written with a UV laser (such as a KrF excimer laser) into the inner cladding B.

In FIG. 2 is shown a system 10 in accordance with the invention for femtosecond inscribing of modified points of altered refractive index in Er:Yb doped phosphosilicate optical fiber. The system 10 comprises a laser 12; half wavelength plate 14 and a polarizer 16 forming together a variable attenuator; mirror 18; objective 20; XY stage 22; a broadband light source 24; a coupler 28 and two optical spectrum analyzers 26. A section of an optical fiber 50 is stretched between two fiber holders, mounted on 3-D translation stages. The assembly including stages with the holders is mounted on the computer controlled high precision air bearing translation stage 22 with nanometre resolution and sub-micron accuracy.

In this example, the laser 12 is operated at a wavelength of 800 nm, producing 150 femtosecond long pulses at a repetition rate of 1 kHz. No special preparation of the fiber is needed and no mask needs to be used. Plastic coating is removed from the stretched section of the fiber prior to the exposure.

Both ends of the stretched section of the fiber are aligned independently in both perpendicular dimensions of the fiber 50 and alignment through the fiber is assessed by monitoring scans between these ends. The fiber 50, shown in FIG. 3, is positioned when the laser beam is considerably attenuated to a level well below the inscription threshold in order to avoid damage in the fiber 50.

The position of the laser's focal point inside the core 52 of fiber 50 in horizontal plane and in vertical plane can be monitored by using two orthogonal placed CCD cameras with integrated long-distance microscopes as shown in FIG. 3.

The writing process of the invention involves focusing tightly the femtosecond laser beam at points in the core of fiber 50. the objective 20 used in this instance can be a 100 times microscopic objective.

An alternative method is to control the power of the laser in such a way that intensity in the central part of the beam reaches the value above the inscription threshold, whilst the intensity at the edges of the beam remains below the threshold value.

Once the inscribing starts the intensity of the laser must be above the “inscription” threshold for altering the refractive index of the fiber 50 but is preferably below the threshold of permanent optical damage. In order to produce a Bragg grating the stage 22 is moved at a constant speed along the fiber 50 in sync with the pulse rate of the laser 12. By doing this each laser pulse produce a grating pitch 59 in the fiber core 52 at equally spaced distances a Bragg grating 60 is produced.

The grating period produced is defined by a ratio of the translation speed of the stage 22 to the pulse repetition rate of the laser 12. The grating reflection transmission can be monitored in situ by using the two optical spectrum analyzers 26 coupled to the amplifier 24. In this case the translation speed is 1.07 mm/s to create a grating pitch δ of 1.07 μm so that the second order resonance occurs within the 1550 nm window.

It is found that such a femtosecond inscription method can be used in materials not regarded as photosensitise including Er:Yb doped phosphosilicate. This may be because the inscription is due to a material restructuring and localised compaction rather than by defect formation as is the case for standard UV inscription.

This fabrication exposure processed can be synchronised with a timed shutter. This is particular useful for creating the laser cavity of the invention where two gratings must be created separated by a precise distance to generate the desired cavity length. In this embodiment use of a shutter produces two 8 mm long uniform fiber Bragg gratings (FBGs) 15 mm apart to create a distributed Bragg reflector (DBR) fiber laser configuration. In an alternative embodiment a fiber laser can be created with only one fiber Bragg grating such as by creating a distributed feedback laser (DFB)

This inscribed DBR fiber laser configuration as shown in FIGS. 4a and 4b as FBG laser 60 (schematically and obviously not to scale nor with the actual number of inscriptions for each grating). The FBG laser 60 comprises a fiber 62 with an outer cladding 64 and an inner Er:Yb co-doped core 66 as with standard Er:Yb co-doped phosphosilicate fiber. Additionally laser 60 comprises two femtosecond laser inscribed FBGs 68 and 70. In this embodiment the FBGs 68 and 70 are 15 mm apart and 8 mm long each.

The transmission profile of the DBR laser cavity 60 measured after fabrication is shown in FIG. 5 which shows spectral power in dBm against wavelength in nm. The resonance features in the spectral profile show that a FBG resonator is present in the Er:Yb co-doped fiber 62.

In FIG. 5 each resonance peak RP corresponds to a longitudinal mode with the dominant lasing mode being at the Bragg centre under the homogenous gain medium. The longitudinal mode spacing in this case measures 43 pm, corresponding to an effective cavity length of 19 mm.

If a 31 mm-long DBR fiber laser with the above characteristics is operated using a 980 nm laser diode as the pump source at 55 mmW pump power, the laser is found to deliver −7.4 dBm at ˜1548.8 nm corresponding to the Bragg wavelength expectedly. The output optical spectrum is a shown in FIG. 6.

Referring to FIG. 7 the relative intensity noise (RIN) of the output from the fiber laser 60 is shown on the plot of spectral power in dB/Hz against MHz. A typical relaxation oscillation peak ROP is produced at 0.261 MHz with an intensity of −94 dB/Hz. As can be seen the noise decrease rapidly at higher frequencies than the peak ROP to levels less than −120 dB/Hz beyond 0.5 MHz.

Increasing the cavity length (and hence gain) of the fiber laser leads to a higher output power.

A feedback mechanism can be incorporated into the invention which will remove the intensity noise peak ROP.

The described method of tightly focussed femtosecond inscription is found to introduce significant polarization dependent characteristics into the gratings 68, 70.

Performing beat signals on the output of fiber laser 60 after a polarizer reveals an absence of any mode beating signals. This indicates that the fiber laser 60 has single polarization mode operation with polarization purity in excess of 40 dB.

It is believed the highly localized index modulation, defined by the focusing geometry, leads to the polarization dependent characteristics in the inscribed fiber grating laser 60. The birefringence, Δn, of gratings 68 and 70 and corresponding grating strength difference between orthogonal polarizations axes ΔR, are on the order Δn˜1.9×10⁵ to 3.8×10⁻⁵ and ΔR˜0.4 dB to 1.5 dB respectively, depending on the focused beam alignment. The relative difference in coupling coefficients between orthogonal polarization axes is therefore ˜0.02 to 0.07. Single-polarization mode operation is hence achieved based on this distinct polarization dependent grating strength, which is stable even at elevated temperatures for femtosecond laser inscribed gratings. consequently fabrication scheme of the invention can be used to tailor the polarization characteristics of fiber grating lasers.

In FIG. 8 is shown the short-term output power stability of fiber laser 60, maintained at room temperature, over 1 hour (30000 samples measurement). FIG. 8 shows the spectral power in dBm against time and it can be seen that the peak to peak fluctuations are less than 0.05 dB fluctuation.

It is found that the FBGs inscribed using the method of the invention have a higher thermal robustness than gratings inscribed by UV light. Each grating 68, 70 is stable tip to 900 degrees compared to 400 or 700 as is typical of type 1 and 2a UV inscribed gratings, and gratings 68, 70 are not permanently damaged until the temperature goes over 1000 degrees. Further it seems that gratings inscribed by this method have a greater stability against erasure by light, making them suitable for use with higher frequencies.

It is also found that fiber lasers constructed in the manner of this invention share this robustness.

To see that fiber laser 60 exhibits the high thermal resistance associated with its femtosecond laser inscribed grating structures 68, 70, the fiber laser 60 can be placed in a tube furnace and its output at 55 mW pump power monitored on an optical spectrum analyzer over a temperature at a range from 20° C. to 605° C.

In FIG. 9 is shown the output LO from the fiber laser 60 and the response FO from an 8 mm long FBG, fabricated in the Er:Yb doped fiber 62 under the same conditions as fiber laser 60. FIG. 9 shows these thermal responses in terms of wavelength (nm) against temperature (degrees Celsius). Both lasing wavelength of the laser output LO and the thermal response of the fiber Bragg grating FO shift with wavelength at a rate measured ˜0.014 nm/° C. The responses LO, FO of the fiber laser 60 and FBG can be seen to be in very close agreement. The fiber laser can operate steadily at each temperature.

In FIG. 10 is shown the output of fiber laser 60 sampled every half hour over 17 hours at through a continuous operation at ˜500° C. over 17 hours. There is no significant performance degradation throughout the period.

Single-polarization mode operation of the fiber Bragg laser 60 is maintained over the entire temperature range.

Due to the precise focusing ability of the set up described above regions of different refractive index can be created which are very small. They can have a diameter in the region of only 2 μm or even much less than 1 μm.

Referring to FIG. 11 there is shown a schematic view of a cross section of fiber 160, created by a similar method to that described above, with the modified volume 168 representing a periodic grating produced as described above. The modified region is in the core 166 rather than cladding 164 and only takes up a small fraction of its area. Region 166 is offset from the center of the core 166 and fiber 160 therefore has an asymmetric distribution of refractive index and a different distribution of refractive index in plane X to in the plane Y.

In FIG. 12 is shown a fiber 260 with elliptical modified region 268. Such non circular modified regions are capable of being created using the highly focused method of inscription inscribed above. Elliptical cross sections can be used to create birefringent properties in the fiber 260. Regions with highly elliptical cross-sections can be used in the production of fiber Bragg lasers as described above to produce a single polarization device.

By controlling the amount of birefigence in the fiber laser cavity it is possible to choose whether to have the laser operate in single or dual polarization mode. Further in dual polarization mode the mode separation can be increase or decreased. Dual polarization fiber laser in accordance with the invention can be used as a microwave signal generator.

In an alternative embodiment a number of gratings can be treated in the laser cavity corresponding to different wavelengths. It is also possible to tailor the polarization characteristics so that the polarization state varies with the wavelength. This can be used in sensing applications.

What is claimed is:

1. A fiber (Bragg) laser comprising a fiber with a cladding and core having a (Bragg) grating inscribed in the core forming a laser cavity.

2. The fiber laser according to claim 1 wherein the core is doped with at least one gain inducing material.

3. The fiber laser comprising a gain fiber which is doped with at least one gain inducing material and has a (Bragg) grating inscribed in the grain fiber forming a laser cavity.

4. The fiber laser according to claim 2 wherein the gain inducing material is a rare earth such as Ytterbium or Erbium.

5. The fiber laser according to claim 2 where the core/gain fiber is ER:Yb co-doped gain fiber and preferably untreated Er:Yb co-doped gain fiber.

6. The fiber laser according to claim 1 comprising a non-photosensitive material such as phosphosilicate glass.

7. The fiber laser according to claim 1 comprising a plurality (Bragg) gratings inscribed in the core/gain fiber forming a laser cavity.

8. The fiber laser according to claim 1 comprising a Distributed Bragg Reflector (DBR) configuration or distributed feedback (DFB) configuration.

9. The fiber laser according to claim 1 comprising a diode laser as the pump source.

10. The fiber laser according to claim 1 which is able to run in continuous operation at high temperatures such as 500 or 1000 degrees Celsius and/or at room temperature.

11. The fiber laser according to claim 1 wherein the inscribed grating cavity has polarization dependent characteristics.

12. The fiber laser according to claim 1 with a single polarization mode.

13. The fiber laser according to claim 12 wherein the single polarization mode is maintained over a temperature range such as 0 to 300 degrees and preferably 0 to 1000 degrees Celsius.

14. The fiber laser according to claim 1 which has birefringence in the grating(s).

15. The fiber laser according to claim 1 wherein the grating has a refractive index profile comprising regions of higher refractive index separated by regions of substantially constant refractive index.

16. The fiber laser according to claim 1 with a dual polarization mode.

17. The fiber laser according to claim 1 when dependent on claim 7 wherein gratings have different Bragg wavelengths.

18. The fiber laser according to claim 17 wherein the laser has tailored polarization characteristics so that it operably has varying output polarization states at different wavelengths.

19. The fiber laser according to claim 1 wherein the grating is located in an off centre segment of the fiber so that the profile of the refractive index of the core gain fiber is asymmetrical and different in different planes of the fiber cross section.

20. A single polarization device comprising a fiber laser according to claim 1.

21. A microwave signal generator comprising a fiber laser according to claim 16.

22. A sensing device comprising a fiber laser according any preceding claim when dependent on claim 18 or 19.

23. A method of fabricating a fiber Bragg laser comprising the steps of:
focussing a laser into the core of an optical fiber at a power sufficient to alter the refractive index at the point of focus to produce a fiber Bragg grating to create a laser cavity.

24. The method according to claim 23 wherein the focussing step is repeated at multiple points along the core to produce a plurality of fiber Bragg gratings to create a laser cavity.

25. The method according to claim 23 wherein the fiber is a rare earth doped fiber and preferably in an Er:Yb co-doped fiber.

26. The method according to any of claim 23 wherein the fiber comprises a non photosensitive material such as phosphosilicate.

27. The method of tailoring polarization characteristics of a fiber laser comprising the steps of claim 23.

28. The method according to claim 27 wherein the polarization characteristics are tailored to produce a fiber laser with single polarization mode operation preferably with polarization purity in excess of 40 dB.

29. The method according to claim 27 wherein the polarization characteristics are tailored to produce a fiber laser with dual polarization mode and the mode separation can be increased or decreased.

30. The method according to claim 23 in which the focussed laser has a wavelength between about 450 to 1000 and preferably around 800 nm.

31. The method according to claim 23 further comprising the step of moving the fiber relative to the laser between inscriptions of points.

32. The method according to claim 31 wherein the fiber is moved relative to the laser at a substantially constant speed.

33. The method according to claim 23 wherein the laser is a pulsed laser preferably pulsed at a rate around 1 kHz.

34. The method according to claim 33 wherein the laser is a femtosecond laser and the pulses preferably have a duration of around 150 fs.

35. The method according to claim 34 wherein the speed is selected relative to the laser pulse rate so that the distance travelled between pulses corresponds to the pitch of gratings inscribed.

36. The method according to claim 23 on which the fiber is held on a moving platform whilst inscription takes place.

37. A method according to claim 24 wherein the fiber exposure to the focussed laser is synchronised with a shutter to generate the desired gap between gratings for the desired cavity length.

38. A method of producing a fiber Bragg laser comprising the steps of focussing a femtosecond pulsed laser beam into a region of the core a rare earth doped fiber, using an objective to focus the beam into a spot size in the core of the fiber the laser beam being at an intensity sufficient to alter the refractive index of the region, moving the fiber with the laser still on at a speed relative to the rate of pulsing of the laser such that there is an alteration of the region the spot covers in its first pulse and a separation from the next region which has its refractive index altered by the laser, the fiber then being moved far enough to inscribe a number of, preferably separated, refractive index altered regions to produce a grating which forms part of the laser cavity of the fiber laser.
